(19) United States
(12) Patent Application Publication
(10) Pub. No.: US 2021/0050180 A1
(43) Pub. Date: Feb. 18, 2021

(54) A Device for Extracting and Placing a Lamella

(71) Applicants: Tescan Brno, s.r.o., Brno (CZ); Tescan Orsay Holding, A.S., Brno (CZ)

(72) Inventors: Andrey Denisyuk, Brno (CZ); Pavel Dolezel, Brno (CZ)

(73) Assignees: Tescan Brno, s.r.o., Brno (CZ); Tescan Orsay Holding, A.S., Brno (CZ)

(21) Appl. No.: 17/043,042

(22) PCT Filed: Mar. 29, 2019
(86) PCT No.: PCT/CZ2019/050013

§ 371 Date: Sep. 29, 2020

(30) Foreign Application Priority Data
Mar. 29, 2018 (CZ) 2018-157

(51) Int. Cl. H01J 37/20; H01J 37/305; H01J 37/28

(52) U.S. Cl. CPC H01J 37/20; H01J 37/3053; H01J 37/28; H01J 2237/20207; H01J 2237/20228; H01J 2237/20235; H01J 2237/20214; H01J 2237/31745

(57) ABSTRACT

A device for creating and placing a lamella comprises a focused ion beam, a scanning electron microscope, a stage for placing at least two specimens enabling tilting, rotation and movement of the specimen. The device further comprises a manipulator terminated by a needle for attaching and transporting the specimen. The manipulator is positioned in a plane perpendicular to the axis of the tilt of the specimen, thereby enabling easy transportation and placing of the lamella into the specimen holder for a transmission electron microscope, so-called grid. The manipulator is adjusted to rotate the needle about its own axis. Thus, it enables inverting of the lamella and its polishing over a layer of semiconductor substrate, on which a semiconductor structure is formed, in case of creating the lamella from a semiconductor device.

### CROSS-REFERENCE TO RELATED APPLICATIONS

This application, filed under 35 USC 371, is a United States National Stage Application of International Application No. PCT/CZ2019/050013, filed Mar. 29, 2019, which claims priority to CZ Application No. 2018-157, filed on Mar. 29, 2018, the disclosures of which are incorporated herein by reference.

### FIELD OF THE INVENTION

The invention relates to a device for extracting and placing a lamella comprising a focused ion beam and a scanning electron microscope, further provided with a stage and a handler.

### BACKGROUND OF THE INVENTION

Requirements for specimens (so called lamellae) for transmission electron microscopes (TEM) and scanning transmission electron microscopes (STEM) increase constantly. It is needed to reach certain width to enable electrons pass through the specimen and it is necessary to reach as straight surface as possible for (S)TEM to give the best image. Therefore, for extracting such accurate lamellae, devices with focused ion beam (FIB) are used, usually in combination with a scanning electron microscope (SEM) to monitor the operation of specimen preparation. By means of such combined device, the lamella of appropriate dimensions, which can be further adjusted or placed in an appropriate specimen holder for further analysis, is cut out of the specimen.

Depending on the specimen characteristics and required analysis, so-called cross view lamella is used, i.e. lamella examining the specimen structure in cross-section, or so-called plane view lamella, which shows the specimen structure in a particular depth of the specimen. Lamella is cut out of the specimen, fixed to the needle of the handler, and transported to the holder in which it may then be adjusted directly in the chamber of the device using FIB or examined by the STEM technology or it may be transported to the holder for TEM (so-called grid) and further processed in it and then transported to a separate TEM device. During the transportation to the new holder, it is necessary to appropriately rotate the lamella so that it is placed in the holder in the correct orientation. Such rotation is usually difficult, and it is necessary to use a handler with a needle rotatable around its own axis. An issue of transportation of the plane view lamella into the grid is solved, for example, in the patent U.S. Pat. No. 7,423,263.

Moreover, the extraction of the lamella is complicated by so-called curtaining effect, which causes the creation of grooves in the lamella in the direction of the incident ions. This phenomenon may be suppressed if an appropriate material with low sputtering rate is applied on the specimen edge over which ions fall on the specimen. Sputtering is then performed over this material.

In case of a semiconductor specimen (device, e.g. a transistor), the extracted lamella may be rotated, and instead of applying a new layer of material, a silicon mass (or other material) may be used, on which a semiconductor structure is formed. Such method is called backside polishing. A disadvantage of this method is again the process of rotating the lamella.

Because of an increasing volume of production of semiconductor components, it is necessary to perform the control more effectively and faster, and above all, with less interventions from the device operator.

The procedure of extracting the lamella from semiconductor specimen disclosed in the patent U.S. Pat. No. 9,653,260 uses a combined FIB-SEM device and a special grid holder, which is able to rotate the lamella independently on the stage, and the operator thus does not need to intervene manually into the device. After cutting out the lamella from the specimen using FIB, the lamella is rotated by the handler and transported into the grid fixed in the holder. Because the handler is in a default position, it is necessary to orient the grid accordingly with respect to the lamella before placing the lamella. The grid holder is then able to rotate the lamella and move it so that it would be possible to make it thinner on both sides. However, this special grid holder requires an additional controller and therefore it makes the whole device more complicated and occupies a space in a proximity of the specimen.

Another state-of-the-art solution of the presented problem can be found in the patent U.S. Pat. No. 9,384,941 B2. However, distribution of the components forming the FIB-SEM apparatus provides rather large and unusual spatial requirements, e.g. two stages. Distribution of the components requires the needle to approach the lamella from any other direction than perpendicular. This causes a difficult manipulation with the lamella.

Furthermore, the extraction process is not observable by the SEM, because by moving the lamella to an extractable position, it leaves the SEM field of view.

### SUMMARY OF THE INVENTION

Drawbacks of the prior solutions mentioned above are eliminated by the present invention. The device for extracting and placing the lamella comprises a focused ion beam column and a scanning electron microscope column on a specimen chamber. In the specimen chamber, a stage for placing at least two specimens is positioned, enabling tilting, rotation, and movement in three mutually perpendicular axes. The stage can be tilted about an axis perpendicular towards a plane defined by the axis of the focused ion beam column and the axis of the scanning electron microscope column. The rotation is performed about the axis, which is vertical with zero tilt. The device further comprises a handler terminated with a needle rotatable about its own axis. The handler is positioned in a plane defined by the axis of the focused ion beam column and the axis of the scanning electron microscope column.

The handler is preferably positioned at an angle of 0°-35° into a horizontal position. It is preferred to position the handler closer to the focused ion beam column. If these conditions are met, the handler is positioned under the focused ion beam column and perpendicularly to the tilting axis of the stage. The specimen can be tilted towards the handler, which is advantageous when working with the specimen.

The stage can be adjusted for placing specimens around the axis of rotation for easy replacement of an examined specimen.

The device may further comprise a gas admission system. During sputtering of the specimen material, a substance accelerating sputtering or a substance eliminating the curtaining effect can be admitted to the proximity of the place of sputtering. During the fixing of the specimen onto a needle of the handler, a substance in gaseous state, which creates a connection between the needle and the specimen, can be admitted.

With the above-mentioned device, it is possible to simplify the process of extracting and placing the lamella. From the place of the specimen, which is to be examined, a lamella is released by FIB from the specimen in a common manner so that the specimen is tilted by its surface perpendicularly to the FIB column, a material on both sides of the future lamella is sputtered by the FIB column, the specimen is tilted to the second position, where the lamella is cut out around the perimeter and stays fixed only to a small portion of the specimen. Then the specimen is tilted to a position so that the area of the lamella and the needle of the handler form an angle of 90°. In this position, the needle is set on the lamella where it is fixed and cut out of the remaining mass of the specimen. The lamella is then raised from the specimen on the needle using the handler.

While preparing the lamella from the semiconductor specimen, when it is desirable to make the lamella even thinner and polish it using FIB from the lower side, the needle is rotated by 180° and thus the lamella is inverted, but its area remains oriented in the same manner. In this position, the lamella is placed in the grid arranged on the stage. In case of specimens, where the rotation is not necessary, the lamella is placed directly in the grid.

Sputtering can occur with the admission of the substance by means of the gas admission system or without it. During the whole time of extracting and placing the lamella, the operation can be monitored by SEM, or alternatively by FIB.

The advantage of the present solution is that it is not necessary to rotate the stage in the direction of the handler before extracting the lamella. The grid is arranged in such orientation that it is not necessary to rotate the lamella any further. The conversion of the lamella and putting it in the grid represents an easy and clear movement for the operator.

### DESCRIPTION OF THE DRAWINGS

FIG. 1 shows a device for processing and examining the specimen according to the invention.

FIGS. 2-7 show a procedure of extracting and placing the specimen in the device according to the invention.

### EXEMPLARY EMBODIMENTS OF THE INVENTION

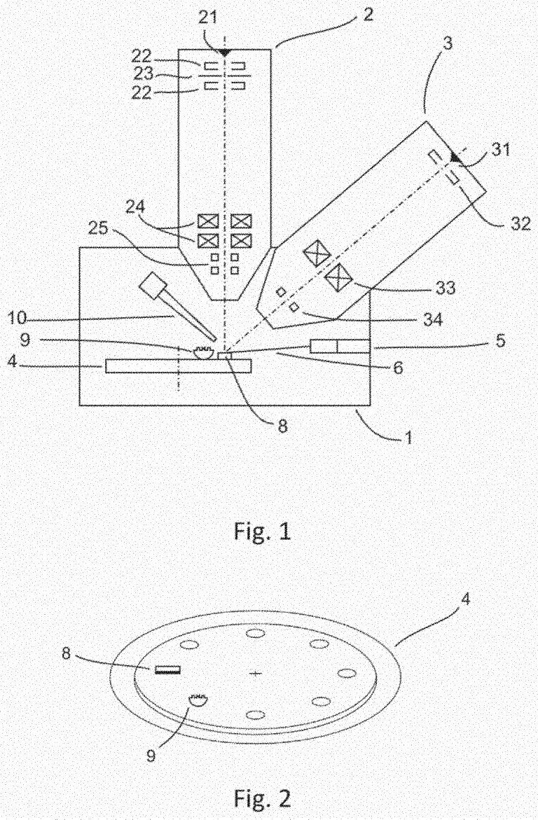

FIG. 1 illustrates a device according to the present invention. On the specimen chamber 1, a scanning electron microscope column 2 is positioned, comprising an electron source 21, an SEM condenser 22, an SEM aperture 23, an SEM objective 24, and SEM scanning coils 25. Further, a focused ion beam column 3 is positioned on the specimen chamber 1 comprising an ion source 31, an FIB extractor 32, an FIB objective lens 33 and an FIB scanning system 34. A stage 4 is positioned in the specimen chamber 1, which enables a gradient of the perpendicular axis to the plane defined by the axis of the focused ion beam column 3 and the axis of the scanning electron microscope column 2, a rotation about the axis which is vertical with zero tilt, and a movement in three mutually perpendicular axes. The device further comprises a handler 5 terminated by a needle 6 that is able to move and rotate about its own axis. The handler 5 is positioned in a plane defined by the axis of the focused ion beam column 3 and the axis of the scanning electron microscope column 2. The handler 5 is positioned closer to the focused ion beam column 3.

The device can be used for example to extract and place a lamella 11 from a semiconductor specimen. A specimen 8 and a grid 9 for placing the lamella 11 are positioned on the stage 4, as shown in FIG. 2. The structure of the semiconductor specimen 8 consists of metal layers and of dielectric layers, which are placed on the layer of a semiconductor substrate, usually silicon. The grid 9 is of a semi-circular shape with projections on which lamellae 11 are positioned. The grid 9 is positioned on the stage 4 vertically, perpendicularly to the plane defined by the axis of the focused ion beam column 3 and the axis of the scanning electron microscope column 2.

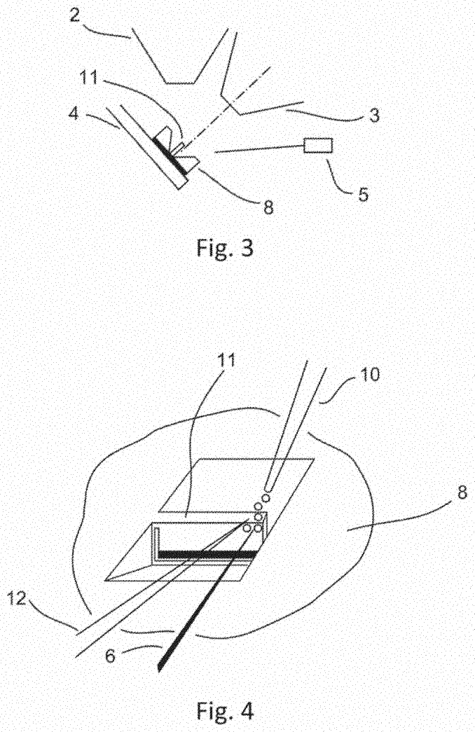

As shown in FIG. 3, the stage 4 is tilted about the axis of the gradient to the focused ion beam column 3 so that the surface of the specimen 8 is perpendicular to the axis of the focused ion beam column 3. In this position, the material of the specimen 8 is sputtered so that two opposite cross-sections of the specimen 8 are sputtered, thereby creating the lamella 11. With this sputtering, it is possible to admit appropriate gas by the gas admission system 10 depending on the exact composition of the specimen 8, for example to accelerate the sputtering or to reduce the curtaining effect. It is possible to monitor the sputtering using the scanning electron microscope or the focused ion beam.

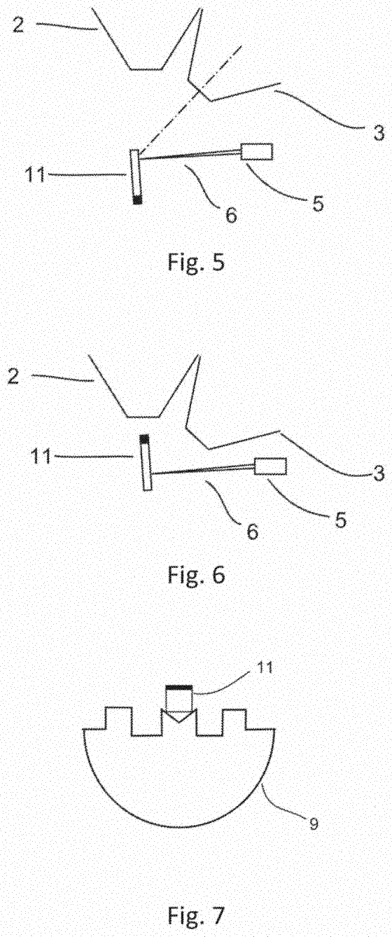

The stage 4 is then tilted into the second position, where the lamella 11 is cut out around the perimeter by ion beam 12 and stays fixed only to a small portion of the specimen 8. As shown in FIG. 4, the stage 4 is tilted so that the needle 6 could proximate to the surface of the lamella 11 perpendicularly. In this position, the needle 6 is fixed to the lamella 11 by a deposition of appropriate material, supplied by the gas admission system 10, using the electron beam or the ion beam 12 or otherwise. The lamella 11 is then released by the ion beam 12 from the specimen 8 and the lamella is raised from the specimen 8 by the handler 5, as shown in FIG. 5. The handler 5 rotates the needle 6 by 180°, thereby converting the lamella 11 (FIG. 6).

As shown in FIG. 7, the lamella 11 in this inverted position is moved by the handler 5 and placed in the grid 9. The lamella 11 can be further polished in the grid 9 using the ion beam 12 preferably from the side of the semiconductor substrate, which prevents the formation of curtaining effect. For polishing and examining the lamella 11 from different sides, it is then possible to use tilting, rotation or movement of the stage 4. During the whole preparation of the lamella 11, the operation can be observed using the scanning electron microscope.

The lamella 11 placed in the grid 9 can be further transported into TEM for further examination.

### LIST OF REFERENCE SIGNS

1—specimen chamber

2—scanning electron microscope column

3—focused ion beam column

4—stage

5—handler

6—needle

8—specimen

9—grid

10—gas admission system

11—lamella

12—ion beam

21—electron source

22—SEM condenser

23—SEM aperture

24—SEM objective

25—SEM scanning coils

31—ion source

32—FIB extractor

33—FIB objective lens

34—FIB scanning system

1. A device for extracting and placing a lamella, comprising a focused ion beam column, a scanning electron microscope column, and a specimen chamber with a stage for positioning of at least two specimens enabling tilting, rotation and movement along three mutually perpendicular axes, wherein the tilting is enabled about the axis perpendicular to a plane defined by the axis of the focused ion beam column and by the axis of the scanning electron microscope column, and the rotation is enabled about the vertical axis, further comprising a handler terminated by a needle, which is able to move and rotate about its own axis, wherein the handler is positioned in a plane defined by the axis of the focused ion beam column and by the axis of the scanning electron microscope column, wherein the handler is placed directly under the focused ion beam column and above an intersection of the axis of the scanning electron microscope column and the axis of the focused ion beam column.

2. The device for extracting and placing a lamella according to claim 1, wherein the handler is placed at an angle 0°-35° from the line perpendicular to the axis of the scanning electron microscope column and intersecting the intersection of the axis of the scanning electron microscope column and the axis of the focused ion beam column, wherein the intersection is the vertex of the angle.

3. The device for extracting and placing a lamella according to claim 1, wherein the handler is positioned closer to the focused ion beam column.

4. The device for extracting and placing a lamella according to claim 1, wherein the stage is adjusted for placing the specimens about the axis of the rotation.

5. The device for extracting and placing a lamella according to claim 1, wherein it further comprises a gas admission system.

6. A method for extracting and placing a lamella comprising the steps of
tilting the specimen to the first position, wherein in the first position the surface of the specimen is perpendicular to the focused ion beam column;
sputtering the sides of the future lamella by the focused ion beam column;
tilting the specimen to the second position;
cutting the edges of the lamella by the focused ion beam column;
attaching the lamella to the needle of the handler and
placing the lamella in the grid
wherein the needle approaches the lamella perpendicularly to the surface of the lamella.

7. The method for extracting and placing the lamella according to the claim 6 wherein upon extracting the lamella from the specimen, the handler is rotated by 180° and the lamella is polished by the focused ion beam column.
